(19) United States
(12) Patent Application Publication
(10) Pub. No.: US 2007/0045610 A1
(43) Pub. Date: Mar. 1, 2007

(54) Transistor device with strained germanium (Ge) layer by selectively growth and fabricating method thereof

(75) Inventors: Min-Hung Lee, Hsinchu (TW); Cheng-Yeh Yu, Hsinchu (TW); Chee-Wee Liu, Hsinchu (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/293,275

(22) Filed: Dec. 5, 2005

(30) Foreign Application Priority Data
Aug. 24, 2005 (TW) 094129017

(51) Int. Cl. H01L 31/109

(52) U.S. Cl. 257/19

(57) ABSTRACT

A transistor device with strained Ge layer by selectively growth and a fabricating method thereof are provided. A strained Ge layer is selectively grown on a substrate, so that the material of source/drain region is still the same as that of the substrate, and the strained Ge layer serves as a carry transport channel. Therefore, the performance of the device characteristics can be improved and the leakage current of the transistor may be approximately commensurate with that of a Si substrate field effect transistor (FET).

### CROSS-REFERENCE TO RELATED APPLICATIONS

This non-provisional application claims priority under 35 U.S.C. § 119(a) on patent application Ser. No(s). 094129017 filed in Taiwan, R.O.C. on Aug. 24, 2005, the entire contents of which are hereby incorporated by reference.

### BACKGROUND

1. Field of Invention

The invention relates to a transistor device and a fabricating method thereof and, in particular, to a transistor device with strained germanium (Ge) layer by selectively growth, and a fabricating method thereof.

2. Related Art

Currently, the metal-oxide-semiconductor (MOS) industry is researched into how to increase the speed of a field effect transistor (FET) to keep scaling down the device. However, when a gate of the transistor is narrowed down to 0.1 μm or even below that, there is a limitation in that the properties of the transistor may not be proportionally scaling down. Many years of research have shown that germanium (Ge) has higher carrier mobility than that of silicon. Therefore, using a strained Ge layer to be a carrier channel instead of Si improves the performance of the transistor device due to the higher carrier mobility.

In a general Ge layer growth process, a relatively thick graded relaxed SiGe buffer layer and a thick relaxed SiGe layer that has uniform Ge concentration must grow before Ge epitaxy. Then, a strained and relatively thin Ge layer grows on a silicon wafer with thick SiGe buffer to avoid defect formation.

For example, a transistor structure with a Ge channel, which is disclosed in U.S. Pat. 6,723,622 B2, has a pure Ge epitaxy layer on a graded relaxed SiGe layer. In order to reduce the defects produced by the lattice mismatch between a silicon substrate and a relaxed SiGe layer, a thicker graded relaxed SiGe buffer, which is about 10 μm thick and has gradual increase of Ge concentration, must grow between them. However, in the epitaxy growth process, a long time is spent on growing the thick SiGe buffer, and the epitaxy growth process is hard to control, such as to cause the problems of high cost, high defect density, rough surface and lack of flatness.

In order to solve the issues, a high dielectric constant (high-K) insulator layer is provided to replace germanium oxide or silicon oxide as an insulator in the transistor. However, because the technology for the high-K insulator layer is not well developed and there are still some know-how issue in the technology, U.S. Pat. No. 6,287,903 B1 provides a ultra thin Ge layer that is about 1.5 nm thick on a silicon substrate, which serves as a passivation layer for preventing the crystalline silicon substrate and the high-K insulator layer from forming an additional interface layer. However, the carrier channel is still made of a silicon material. Therefore, a FET transistor that uses a method of direct epitaxy to grow an ultra thin Ge layer on a silicon substrate not only can produce a high quality strained Ge layer but also has the advantage of reduced cost in this case.

In addition, as disclosed in U.S. Pat. 6,621,131 B2, by the steps of forming a cavity in the source/drain region of a substrate and selectively growing a SiGe alloy in the cavity, a strained-Si layer with a compressive strain is formed by compressing a channel by a higher lattice constant of the alloy. Thus the performance of the p-channel field transistors (PFETs) can be improved. However, although a similar method using selectively growing is provided herein, the structure purpose in this case is different from the structure according to the invention.

### SUMMARY

One objective of the invention is to provide a transistor device with a strained Ge layer by selectively growth, and a fabricating method thereof, to solve the foregoing problems.

Therefore, according to the invention, an embodiment of the method for fabricating a transistor device substrate with a strained germanium (Ge) layer by selectively growth includes the steps of: providing a substrate; forming a strained Ge layer on the substrate; forming a passivation layer on the strained Ge layer; forming a sacrificial layer on the passivation layer; forming a photo resist pattern on the sacrificial layer; using the photo resist pattern as an etching mask to etch the sacrificial layer, the passivation layer and the strained Ge layer where they are uncovered by the photo resist pattern until the substrate is exposed; removing the photo resist pattern; forming a silicon layer on the exposed substrate surface; and removing the sacrificial layer.

The invention provides another embodiment of the method for fabricating a transistor device substrate with a strained germanium (Ge) layer by selectively growth, including the steps of: providing a substrate; forming a sacrificial layer on the substrate; forming a photo resist pattern on the sacrificial layer; using the photo resist pattern as an etching mask to etch the sacrificial layer and the substrate where they are uncovered by the photo resist pattern to form a cavity; removing the photo resist pattern; forming a strained Ge layer in the cavity; and forming a passivation layer on the strained Ge layer.

Herein the substrate includes a semiconductor substrate and a silicon buffer layer thereon. Furthermore, the material for the strained Ge layer can be Ge or SiGe alloy, which has a thickness between 1 nm and 100 nm, preferably between 2 nm and 10 nm. The passivation layer is used for protecting the interface between the strained Ge layer and the dielectric layer of the transistor device. The thickness of the passivation layer can be between 0.5 nm and 10 nm. However when the transistor device is formed, the preferred thickness of the passivation layer is between 0.5 nm and 3 nm.

Moreover, the invention provides a transistor device with a strained germanium by selectively growth, including: a semiconductor substrate, a silicon layer, a strained Ge layer and a passivation layer. The silicon layer is on the semiconductor substrate and has a cavity. The strained Ge layer is in the cavity and the passivation layer is formed on the strained Ge layer.

Also, a dielectric layer can be formed on the passivation layer. A gate can be disposed on the dielectric layer. A source/drain region is formed at the two sides of the gate, which are separated from the strained Ge layer.

Herein the source/drain region can be formed by impurity doping or a metal Schottky contact process. The impurity doping process can be an ion implantation process or a diffusion process. In addition, an annealing process can be undertaken after the impurity doping process. The annealing process can be a rapid thermal process (RTP), a rapid thermal annealing (RTA) process or a furnace annealing process.

Materials for the strained Ge layer can be Ge or SiGe alloy, which has a thickness of 1 nm to 100 nm. The preferred thickness is between 2 nm and 10 nm. However when the transistor device is formed, the preferred thickness of the passivation layer is between 0.5 nm and 3 nm.

In summary, according to the invention, by selectively growing a strained Ge layer on a substrate, the material for the source/drain region can remain the same as that of the substrate. The forming of the strained Ge layer is mainly for the purpose of providing a carrier channel to improve the driving current while the device forms. The amount of current leakage is close to that of the present silicon based field effect transistor.

### BRIEF DESCRIPTION OF THE DRAWINGS

The present invention will become more fully understood from the detailed description given below, which is for illustration only and thus is not limitative of the present invention, wherein:

FIGS. 1A to 1I show the process diagrams of an embodiment of a method for fabricating a transistor device with strained germanium by selectively growth according to the invention; and

FIGS. 2A to 2F show the process diagrams of another embodiment of a method for fabricating a transistor device with strained germanium by selectively growth according to the invention.

### DETAILED DESCRIPTION

The main concept of the invention is to selectively grow an ultra thin strained Ge layer on a silicon substrate, which serves as a channel for increasing the speed of a device while the source/drain region still consists of silicon based material. According to the invention, is not only the driving current, but also the current leakage status of the transistor is similar to that of a silicon based field effect transistor, which can be further applied to integrated circuits or other devices.

As disclosed in U.S. Pat. 6,621,131 B2, a cavity is formed in the source/grain region of the substrate followed by selectively growth SiGe alloy in the cavity to form a compressively strained Si by the larger lattice constant of the alloy, causing the compression of the channel. Although in this specification, a similar method of selectively growth is provided when compared to the related art, there are still some features that distinguish them from the related art for increasing carrier mobility: the material embedded in the channel area is different from that of the substrate in the related art, while they are the same in the specification; the material for the source/drain region is the same as that of a substrate for reducing the current leakage in the related art, while they are different in the specification. For the above reasons, the process, purpose and application of the invention are totally different from those of the related art.

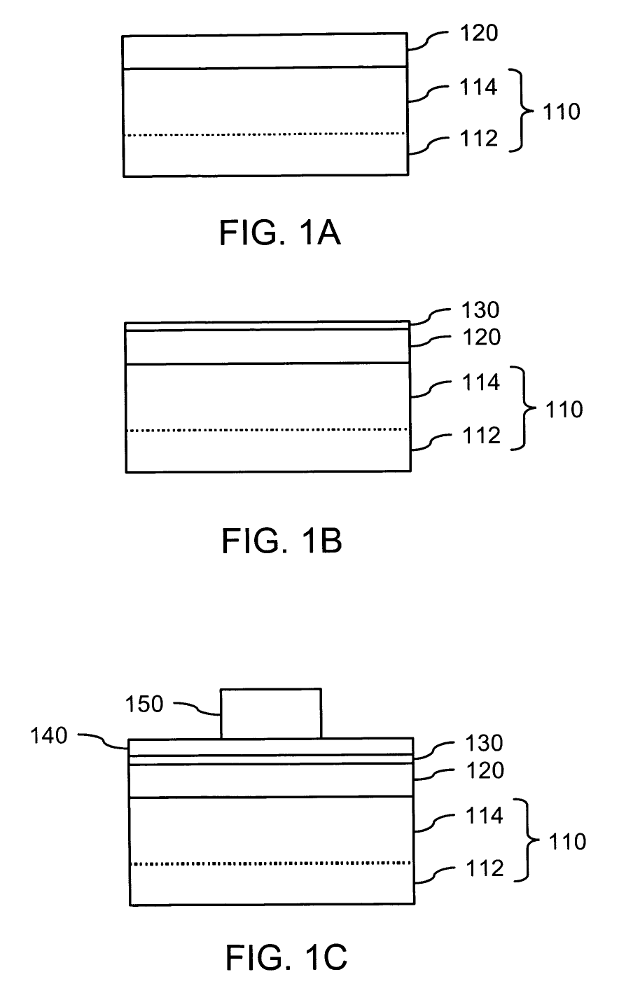

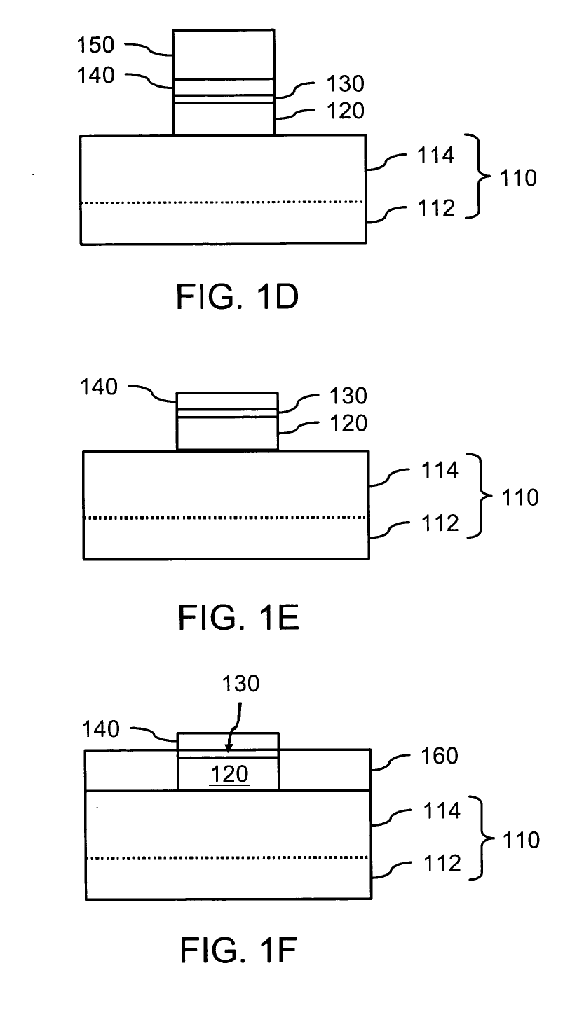

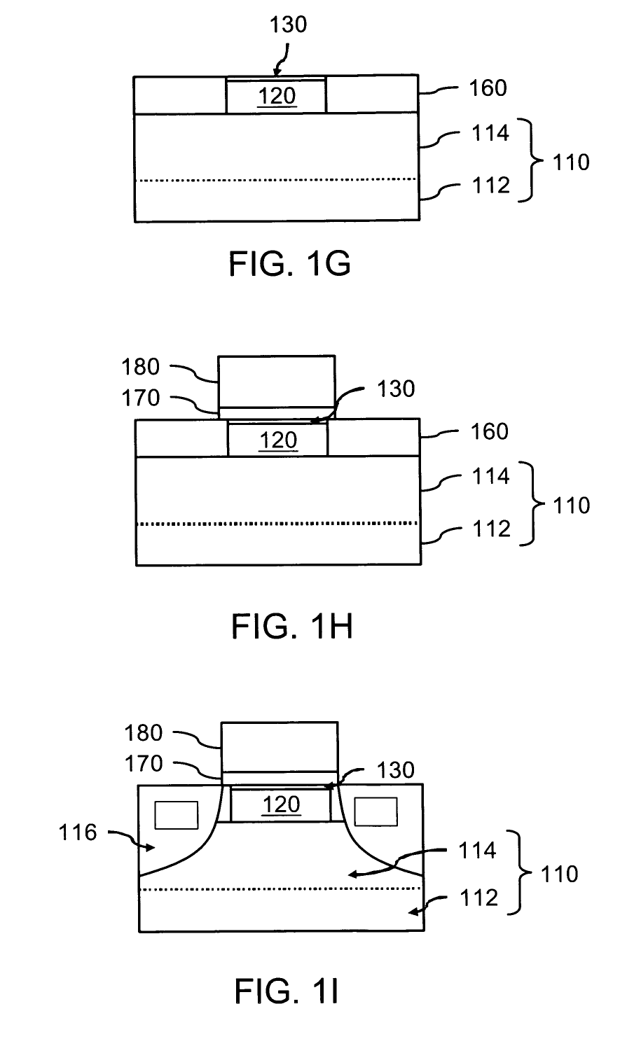

Please refer to FIGS. 1A˜1I, which are the process diagrams showing an embodiment of a fabricating method for a transistor device with a selectively growth strained Ge layer. As shown in FIG. 1, a strained Ge layer 120 is formed on a substrate 110. Then a passivation layer 130 is formed on the strained Ge layer 120. As shown in FIG. 1B, a sacrificed layer 140 is formed on the passivation layer 130 and a photo resist pattern 150 is then formed on the sacrificed layer 140, which is shown in FIG. 1C. Next, using the photo resist pattern as an etching mask, the uncovered sacrificed layer 140, the uncovered passivation layer 130 and the uncovered strained Ge layer 120 are etched until exposing the substrate 110. As shown in FIG. 1D, a photolithography technique can be used to define the gate and to form a photo resist pattern for later etching. After removing the photo resist pattern 150 (shown in FIG. 1E), a silicon layer 160 is formed on the exposed substrate 110, which is shown in FIG. 1F. After forming the silicon layer 160 and further removing the sacrificed layer 140, a basic transistor device structure is obtained, as shown in FIG. 1G. Furthermore, a fabricating process for the device can proceed based on the structure. After a dielectric layer 170 is formed on the passivation layer 130, a conductive layer 180 is further disposed on the dielectric layer 170 as a gate for the transistor device, as shown in FIG. 1H. Finally, a source/drain region 116 is formed at two sides of the gate (the conductive layer 180), wherein the source/drain region 116 is separated form the strained Ge layer 120 and a transistor device is formed, as shown in 1I. Herein, the passivation layer works for protecting the interface between the strained Ge layer and the dielectric layer of the transistor device. The thickness of the passivation layer can be between 0.5 nm and 10 nm, while after the transistor device forms, the preferred thickness of the passivation layer is between 0.5 nm and 3 nm.

The substrate 110 can include a semiconductor substrate 112 and a silicon buffer layer 114 on the semiconductor substrate 112. The semiconductor substrate 112 can be a semiconductor composition substrate, such as a silicon substrate, an insulator substrate, a crystalline silicon substrate, silicon on insulator substrate (SOI) or a relaxed SiGe buffer substrate. And the semiconductor substrate can have a lattice orientation of (100), (110) or (111).

Furthermore, the material for the strained Ge layer can be pure Ge or SiGe alloy and the material for the dielectric layer can be silicon oxide or high-K dielectric material. The photolithography technique can be processed by a stepper.

The process mentioned above can be accomplished by performing a low temperature epitaxy process. This low temperature epitaxy process can be a chemical vapor deposition (CVD) method or a molecule beam epitaxy (MBE) method. Moreover, the process temperature of the low temperature epitaxy process can be between 200° C. and 600° C. Herein the epitaxy thickness of the strained Ge layer can range from 1 nm to 100 nm and the preferred thickness is between 2 nm and 10 nm.

Using an epitaxy process as an example, an ultra high vacuum chemical vapor deposition (UHVCVD) system is used to grow a 40 nm thick silicon buffer layer on a crystalline silicon substrate at about 525° C. for obtaining a substrate. The silicon buffer layer has the benefit for growth of an epitaxy thin Ge layer. Next, the ultra high vacuum chemical vapor deposition (UHVCVD) system is used again to grow a 4 nm thick compress-strained thin Ge layer on the substrate to form a carrier channel of a transistor at about 525□. The ultra high vacuum chemical vapor deposition (UHVCVD) system is further used to grow a 1 nm thin silicon layer to form a silicon film passivation layer at about 525□. At this time, a basic field effect transistor is obtained. In order that the selectively epitaxy growth process can later proceed for enabling the epitaxy thin Ge layer to serve as a carrier channel when the transistor device forms, a sacrificed oxidation layer is formed on the silicon film passivation layer. This sacrificed oxidation layer can be used based on the photolithography technology to define a gate. An etching process is then done to etch out the source/drain region, the sacrificed oxidation layer, the silicon film passivation layer and the epitaxy thin Ge layer where they are not covered by the photo resist pattern. After the etching process is finished, remove the photo resist pattern, and use a selectively growth method to form a pure silicon layer in the source/drain region. The sacrificed oxidation layer is then removed, by which a basic transistor device structure is obtained. Based on that, a fabricating process for a device can be further performed to sequentially form a gate insulator layer and a gate electrode on silicon film passivation layer, and form a source/drain region at the two sides of the gate so that a transistor device can be obtained.

In other words, as shown in FIG. 1G, a transistor device with a strained Ge layer by selectively growth is obtained mainly by the processes of forming a cavity on a substrate 110, forming a strained Ge layer 120 in the cavity and forming a passivation layer 130 on the strained Ge layer 120. The substrate 110 is composed by stacking together a semiconductor substrate 112 and a silicon buffer layer 114. This semiconductor substrate 112 can be a semiconductor composition substrate, such as a silicon substrate, an insulator substrate, a crystalline silicon substrate, a silicon on insulator substrate (SOI) or a relaxed SiGe buffer substrate. And the semiconductor substrate can have a lattice direction of (100), (110) or (111). This silicon buffer layer can be an epitaxy silicon buffer layer. The material of the strained Ge layer can be pure Ge or SiGe alloy, which can have a thickness of 1 nm to 100 nm. The preferred thickness of the strained Ge layer is between 2 nm and 10 nm. Next, the passivation layer can be a silicon film passivation layer, which can be an epitaxy thin silicon layer. Herein a thickness of the epitaxy thin silicon layer can be between 0.5 nm and 10 nm, where the preferred thickness is between 0.5 nm and 3 nm, which is obtained after the device completes. Furthermore, as shown in FIG.1I, a transistor device with a strained Ge layer by selectively growth can be further obtained by the following steps: forming a dielectric layer on the passivation layer; disposing a gate on the dielectric layer; and forming a source/drain region 116 at the two sides of the gate (the conductive layer 180) in the substrate, wherein the source/drain region 116 is separated from the strained Ge layer 120. Because the surface of the substrate is protected by the passivation layer, the dielectric layer can be made by silicon oxide, which is a stable interface used in the present silicon process, or other high-K dielectric materials.

In this process, the source/drain region can be formed by an impurity doping method or a metal Schottky contact method. The impurity doping method can be an ion implantation process or a diffusion process. Furthermore, after the impurity doping process, an annealing process can proceed. The annealing process can be a rapid thermal process (RTP), a rapid thermal annealing (RTA) process or a furnace annealing process.

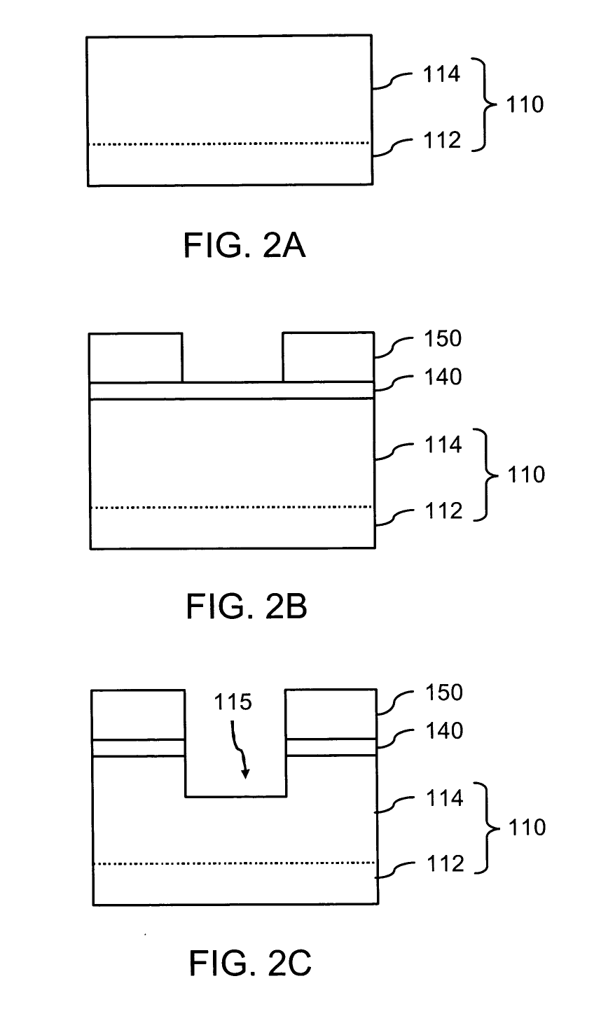

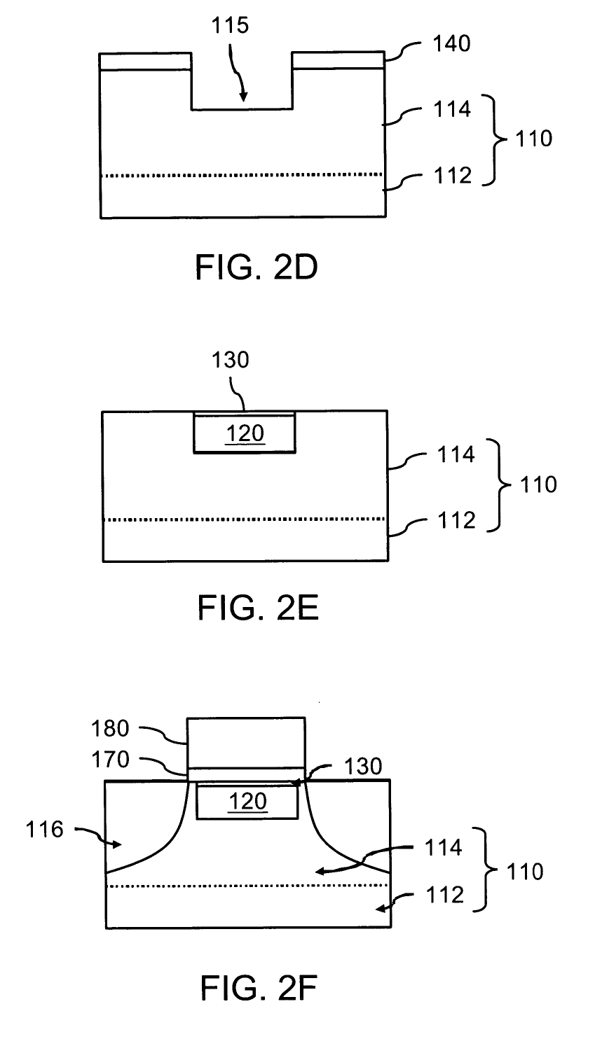

In addition, a transistor device with a strained Ge layer by selective growth also can be obtained by the following process. Please refer to FIGS. 2A˜2F, showing another embodiment of a method for fabricating a transistor device with a strained Ge layer by selective growth. First, as shown in FIG. 2A, a substrate 110 is provided. Then a sacrificed layer 140 is formed on the substrate 110, followed by forming a photo resist pattern 150 on the sacrificed layer 140, as shown in FIG. 2B. Next, as shown in FIG. 2C, use the photo resist pattern 150 as an etching mask for etching the uncovered sacrificed layer 140 and the substrate 110 to form a cavity 115 on the substrate 1 10. After the etching process is competed, as shown in FIG. 2D, remove the photo resist pattern 150. And as shown in FIG. 2E, after forming a strained Ge layer 120 in the cavity and forming a passivation layer 130 on the strained Ge layer 120, a basic structure of the transistor device similar to that in FIG. 1G can also be obtained.

Hereinafter, a more complete transistor device can be further obtained by the following steps: forming a dielectric layer 170 on the passivation layer 130; disposing a conductive layer 180 on the dielectric layer 170 to form a gate of a transistor device; and forming a source/drain region 116 at the two sides of the gate (the conductive layer 180) in the substrate 110, wherein the source/drain region 116 is separated from the strained Ge layer 120. As shown in FIG. 2F, a similar structure to that shown in the FIG. 1I is also obtained.

In this process, the source/drain region can be formed by an impurity doping method or a metal Schottky contact method. The impurity doping method can be an ion implantation process or a diffusion process. Furthermore, after the impurity doping process, an annealing process can proceed. The annealing process can be a rapid thermal process (RTP), a rapid thermal annealing (RTA) process or a furnace annealing process.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments, which do not depart from the spirit and scope of the invention.

What is claimed is:

1. A method for fabricating a transistor device with a strained germanium (Ge) layer by selectively growth comprising:
providing a substrate;
forming a strained Ge layer on the substrate;
forming a passivation layer on the strained Ge layer;
growing a sacrificed layer on the passivation layer;
forming a photo resist pattern on the sacrificed layer;
using the photo resist pattern as a etching mask for etching the sacrificed layer, the passivation layer and the strained Ge layer which are not covered by the photo resist pattern till expose the substrate;
removing the photo resist pattern;
forming a silicon layer on the exposed substrate; and
removing the sacrificed layer.

2. The method of claim 1, wherein the step of providing a substrate comprising:
providing a semiconductor substrate; and
forming a silicon buffer layer on the semiconductor substrate.

3. The method of claim 2, wherein the semiconductor substrate is a semiconductor composition substrate.

4. The method of claim 2, wherein the semiconductor substrate has a lattice orientation, which is one of(100), (110) and (111).

5. The method of claim 1, wherein the steps of forming the strained Ge layer on the substrate, forming the passivation layer on the strained Ge layer, and forming the silicon layer on the exposed substrate are accomplished by using a low temperature epitaxy process.

6. The method of claim 5, wherein the low temperature epitaxy process is one of a chemical vapor deposition (CVD) method or a molecule beam epitaxy (MBE) method.

7. The method of claim 5, wherein a process temperature of the low temperature epitaxy process is between 200° C. and 600° C.

8. The method of claim 5, wherein the strained Ge layer has an epitaxy thickness of 1 nm to 100 nm.

9. The method of claim 8, wherein the strained Ge layer has a preferred epitaxy thickness of 2 nm to 10 nm.

10. The method of claim 5, wherein the passivation layer has an epitaxy thickness of 0.5 nm to 10 nm.

11. The method of claim 1, wherein the step of forming the photo resist pattern on the sacrificed layer is undertaken by using a photolithography technique.

12. The method of claim 11, wherein the photolithography technique uses a stepper.

13. The method of claim 1, wherein the sacrificed layer is a sacrificed oxidation layer.

14. The method of claim 13, wherein a material of the sacrificed oxidation layer is an amorphous material.

15. The method of claim 1, wherein the strained Ge layer is one of a pure Ge layer and a SiGe alloy layer.

16. The method of claim 1, wherein the passivation layer is a silicon film passivation layer.

17. A method for fabricating a transistor device with a strained germanium (Ge) layer by selectively growth comprising:
providing a substrate;
forming a sacrificed layer on the substrate;
forming a photo resist pattern on the sacrificed layer;
using the photo resist pattern as a etching mask for etching the sacrificed layer, and the substrate which are not covered by the photo resist pattern to form a cavity;
removing the photo resist pattern;
forming a strained Ge layer in the cavity; and
forming a passivation layer on the strained Ge layer.

18. The method of claim 17, wherein the step of providing a substrate comprising:
providing a semiconductor substrate; and
forming a silicon buffer layer on the semiconductor substrate.

19. The method of claim 18, wherein the semiconductor substrate is a semiconductor composition substrate.

20. The method of claim 18, wherein the semiconductor substrate has a lattice orientation, which is one of (100), (110) and (111).

21. The method of claim 17, wherein the steps of forming the strained Ge layer in the cavity, and forming the passivation layer on the strained Ge layer are accomplished by using a low temperature epitaxy process.

22. The method of claim 21, wherein the low temperature epitaxy process is one of a chemical vapor deposition (CVD) method or a molecule beam epitaxy (MBE) method.

23. The method of claim 21, wherein a process temperature of the low temperature epitaxy process is between 200° C. and 600° C.

24. The method of claim 21, wherein the strained Ge layer has an epitaxy thickness of 1 nm to 100 nm.

25. The method of claim 24, wherein the strained Ge layer has a preferred epitaxy thickness of 2 nm to 10 nm.

26. The method of claim 21, wherein the passivation layer has an epitaxy thickness of 0.5 nm to 10 nm.

27. The method of claim 17, wherein the step of forming the photo resist pattern on the sacrificed layer is undertaken by using a photolithography technique.

28. The method of claim 27, wherein the photolithography technique uses a stepper.

29. The method of claim 17, wherein the sacrificed layer is a sacrificed oxidation layer.

30. The method of claim 29, wherein a material of the sacrificed oxidation layer is an amorphous material.

31. The method of claim 17, wherein the strained Ge layer is one of a pure Ge layer and a SiGe alloy layer.

32. The method of claim 17, wherein the passivation layer is a silicon film passivation layer.

33. The method of claim 17, further comprising a step of removing the sacrificed layer.

34. A transistor device with a strained Ge layer by selectively growth comprising:
a semiconductor substrate;
a silicon layer on the semiconductor substrate wherein the silicon layer has a cavity;
a strained Ge layer in the cavity; and
a passivation layer on the strained Ge layer.

35. The transistor device of claim 34, wherein the strained Ge layer is an epitaxy thin Ge layer.

36. The transistor device of claim 34, wherein the strained Ge layer is one of a pure Ge layer and a SiGe alloy layer.

37. The transistor device of claim 34, wherein the strained Ge layer has a thickness of 1 nm to 100 nm.

38. The transistor device of claim 37, wherein the strained Ge layer has a preferred thickness of 2 nm to 10 nm.

39. The transistor device of claim 34, wherein the silicon layer is a silicon buffer layer.

40. The transistor device of claim 35, wherein the silicon buffer layer is an epitaxy silicon buffer layer.

41. The transistor device of claim 34, wherein the semiconductor substrate is a semiconductor composition substrate.

42. The transistor device of claim 41, wherein the semiconductor composition substrate is one of a silicon substrate, a crystalline silicon substrate, a silicon on insulator (SOI) substrate and a relaxed SiGe buffer substrate.

43. The transistor device of claim 34, wherein the semiconductor substrate has a lattice orientation, which is one of (100), (110) and (111).

44. The transistor device of claim 34, wherein the passivation layer is a silicon film passivation layer.

45. The transistor device of claim 44, wherein the silicon film passivation layer is an epitaxy thin silicon layer.

46. The transistor device of claim 45, wherein the epitaxy thin silicon layer has a thickness of 0.5 nm to 10 nm.

47. The transistor device of claim 46, wherein the epitaxy thin silicon layer has a preferred thickness of 0.5 nm to 3 nm.

48. The transistor device of claim 34, further comprising:
a dielectric layer on the passivation layer;
a gate on the dielectric layer; and
a source/drain region located at the two sides of the strained Ge layer and is separated form the strained Ge layer.

49. The transistor device of claim 48, wherein a material of the dielectric layer is one of a silicon oxide and a high-K dielectric material.

50. The transistor device of claim 48, wherein a material of the gate is one of a polysilicon, a polysilicon germanium and a metal material.

51. The transistor device of claim 48, wherein the source/drain is formed by a method selected from the group consisting of an impurity doping process and a metal Schottky contact process.

52. The transistor device of claim 51, wherein the impurity doping process is selected from the group consisting of an ion implantation method and a diffusion method.

53. The transistor device of claim 51, further comprising an annealing process and a diffusion process after the impurity doping process wherein the annealing process and the diffusion process are selected from the group consisting of a rapid thermal process and a furnace annealing process.

54. The transistor device of claim 53, wherein the rapid thermal process is a rapid thermal annealing (RTA) process.
